(19) United States
(12) Patent Application Publication
(10) Pub. No.: US 2026/0339197 A1
(43) Pub. Date: Oct. 29, 2026

(54) RESIST COMPOSITION, LAMINATE, AND PATTERNING PROCESS

(71) Applicant: SHIN-ETSU CHEMICAL CO., LTD., Tokyo (JP)

(72) Inventors: Satoshi KUSAMA, Joetsu-shi (JP); Kousuke OHYAMA, Joetsu-shi (JP); Shun KIKUCHI, Joetsu-shi (JP); Ryo NISHIKAWA, Joetsu-shi (JP); Masaki OHASHI, Joetsu-shi (JP)

(73) Assignee: SHIN-ETSU CHEMICAL CO., LTD., Tokyo (JP)

(21) Appl. No.: 19/464,784

(22) Filed: Jan. 30, 2026

(30) Foreign Application Priority Data
Feb. 4, 2025 (JP) 2025-017136

(51) Int. Cl. G03F 7/004; G03F 7/11; G03F 7/20

(52) U.S. Cl. CPC G03F 7/0042; G03F 7/11; G03F 7/2004; G03F 7/2059

(57) ABSTRACT

The present invention is a resist composition containing a metal complex represented by the following general formula (1) and a solvent, where R represents a hydrogen atom, a hydrocarbylcarbonyl group having 1 to 20 carbon atoms, or a hydrocarbyl group having 1 to 20 carbon atoms and optionally containing a heteroatom; and X represents a halogen atom or a hydrocarbyl group having 1 to 20 carbon atoms and optionally containing a heteroatom. This can provide: a resist composition that is excellent in sensitivity, resolution, and LWR in photolithography using a high-energy beam, and is stable and can be easily handled; a laminate including a resist film obtained from the resist composition; and a patterning process using the resist composition.

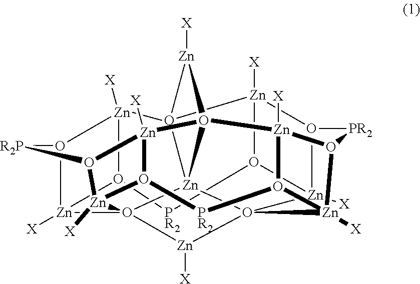

### TECHNICAL FIELD

The present invention relates to: a resist composition; a laminate; and a patterning process.

### BACKGROUND ART

While a higher integration density, higher operating speed and lower power consumption of LSIs are demanded to comply with the expanding IoT market, miniaturization of pattern rule is progressing rapidly. In particular, logic devices drive forward the miniaturization technology. As the advanced miniaturization technology, devices of 10-nm node are manufactured in a mass scale by the double, triple or quadro-patterning version of the immersion ArF lithography. Furthermore, the experimental mass-scale manufacture of 7-nm node devices by the next-generation extreme ultraviolet ray (EUV) lithography of wavelength 13.5 nm has started.

As miniaturization advances, image blurs due to acid diffusion are regarded as a problem (Non Patent Document 1). In order to ensure resolution for fine patterns with a processed size of the post-45 nm generation, it is suggested that not only the enhancement of dissolution contrast, which has been proposed previously, but also the controlling of acid diffusion is important (Non Patent Document 2). In chemically amplified resist compositions, however, the sensitivity and the contrast are enhanced by acid diffusion. Accordingly, an attempt to minimize acid diffusion by lowering the temperature of post-exposure baking (PEB) and shortening the PEB time lowers the sensitivity and contrast markedly.

It is effective to control the acid diffusion by adding an acid generator that generates a bulky acid. Accordingly, it has been proposed to copolymerize a polymer with an acid generator in the form of an onium salt having polymerizable olefin. In the patterning of resist films with a processed size of the post-16 nm generation, however, it is considered that patterning is impossible with chemically amplified resist compositions in view of the acid diffusion. Accordingly, development of a non-chemically amplified resist composition is desired.

Examples of materials for a non-chemically amplified resist composition include polymethyl methacrylate (PMMA). PMMA is a positive resist material whose solubility in an organic solvent developer increases due to decreased molecular weight caused by scission of the main chain by irradiation with an electron beam (EB) or EUV. However, PMMA does not have a cyclic structure, and therefore, has disadvantages that etching resistance is low and the amount of outgassing during exposure is large.

Hydrogensilsesquioxane (HSQ) is a material for a negative resist composition which turns insoluble in an alkaline developer through crosslinking by condensation reaction of silanol generated by EB or EUV irradiation. Calixarene substituted with chlorine also functions as a material for a negative resist composition. These materials have a small molecular size prior to crosslinking and are free from causing blurs due to acid diffusion, and therefore, exhibit smaller edge roughness and very high resolution. Accordingly, the materials have been used as a pattern transfer material to show the resolution limit of the exposure apparatus. These materials, however, are insufficient in sensitivity, and further improvement is required.

The number of photons in EUV exposure being small is a factor that causes difficulties in developing materials for EUV lithography. The energy of EUV is much higher than that of an ArF excimer laser beam, and the number of photons in EUV exposure is 1/14 of that of ArF exposure. Furthermore, the size of the pattern formed by EUV exposure is half of that in ArF exposure or less. Therefore, EUV exposure is easily affected by variation in the number of photons. The variation in the number of photons in a radiation light region of extremely short wavelengths is the physical phenomenon of shot noise, and it is impossible to eliminate the influence of the variation. Therefore, so-called probability theory (stochastics) is attracting attention. The influence of shot noise cannot be eliminated, but there is discussion of how to reduce this influence. Due to the influence of shot noise, not only are critical dimension uniformity (CDU) and line width roughness (LWR) increased, a phenomenon that a hole gets blocked at a probability of one to several millions is observed. If a hole gets blocked, conduction failure occurs and the transistor does not function, and the performance of the entire device is adversely affected.

As a means for reducing the influence of shot noise on the side of the resist, there has been proposed an inorganic resist composition containing, as a nucleus, an element that greatly absorbs EUV (Patent Document 1). However, although inorganic resist compositions have comparatively high sensitivity, sensitivity is still insufficient, and such compositions have many issues, such as insufficient solubility in solvents for resist compositions, storage stability, and defects.

Non Patent Document 3 proposes a negative resist composition containing a tin compound. This composition is a non-chemically amplified resist composition mainly containing the element tin, which greatly absorbs EUV light, and stochastics is improved, and sensitivity and resolution are greatly improved. However, the composition has a deficiency in stability, and has problems that the resist composition is degraded during storage, performance is altered due to Post PEB Delay (PPD) following PEB (time elapsed after PEB until development), etc.

### CITATION LIST

### Patent Literature

Patent Document 1: JP2015-108781A

### Non Patent Literature

Non Patent Document 1: SPIE Vol. 5039 p1 (2003)
Non Patent Document 2: SPIE Vol. 6520 p65203L-1 (2007)
Non Patent Document 3: SPIE Vol. 9051 p90511B-1 (2014)

### SUMMARY OF INVENTION

### Technical Problem

The present invention has been made in view of the above-described circumstances, and an object thereof is to provide: a resist composition that is excellent in sensitivity, resolution, and LWR in photolithography using a high-energy beam, and is stable and can be easily handled; a laminate including a resist film obtained from the resist composition; and a patterning process using the resist composition.

### Solution to Problem

To achieve the object, the present invention provides a resist composition comprising a metal complex represented by the following general formula (1) and a solvent,

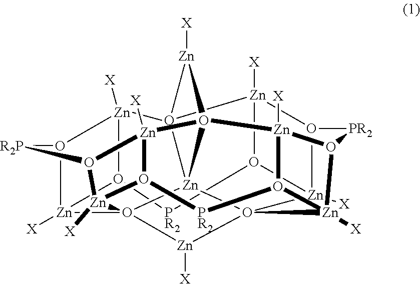

wherein R represents a hydrogen atom, a hydrocarbylcarbonyl group having 1 to 20 carbon atoms, or a hydrocarbyl group having 1 to 20 carbon atoms and optionally containing a heteroatom; and X represents a halogen atom or a hydrocarbyl group having 1 to 20 carbon atoms and optionally containing a heteroatom.

Such a resist composition is excellent in sensitivity, resolution, and LWR in photolithography using a high-energy beam, and is stable and can be easily handled.

The present invention also provides a laminate comprising:
a substrate; and
a resist film obtained from the above-described resist composition on the substrate.

Such a laminate has a resist film having high sensitivity, exhibits excellent limiting resolution, is effective for precise fine processing, and moreover, is also excellent in post PEB delay stability.

In this case, the laminate preferably further comprises a resist underlayer film between the substrate and the resist film.

In the present invention, the laminate can be as described above.

The present invention also provides a patterning process comprising the steps of:
forming a resist film by using the above-described resist composition on a substrate or on a resist underlayer film of a substrate on which the resist underlayer film has been laminated;
exposing the resist film by using a high-energy beam; and
developing the exposed resist film by using a developer.

According to such a patterning process, it is possible to provide a patterning process using a resist composition that is excellent in sensitivity, resolution, and LWR in photolithography using a high-energy beam, and is stable and can be easily handled.

In this event, the high-energy beam used is preferably an electron beam or an extreme ultraviolet ray.

In the inventive patterning process, it is preferable to use such a high-energy beam.

### Advantageous Effects of Invention

As described above, the inventive resist composition can achieve both high sensitivity and high resolution in photolithography using a high-energy beam, especially EB lithography and EUV lithography, is excellent in LWR, furthermore, has favorable stability, and can be handled easily, and therefore, is extremely useful in fine patterning.

### BRIEF DESCRIPTION OF DRAWINGS

FIG. 1 is a schematic view showing an example of the inventive laminate.

### DESCRIPTION OF EMBODIMENTS

As stated above, there have been demands for the development of: a resist composition that is excellent in sensitivity, resolution, and LWR in photolithography using a high-energy beam, especially EB lithography and EUV lithography, and is stable and can be easily handled; a laminate including a resist film obtained from the resist composition; and a patterning process using the resist composition.

To achieve the object, the present inventors have studied earnestly and found out that a resist composition mainly containing a metal complex having a particular structure can give a resist film that has high sensitivity, exhibits excellent resolution and LWR, furthermore, is also excellent in stability, and is extremely effective for precise fine processing. Thus, the present invention has been achieved.

That is, the present invention is a resist composition comprising a metal complex represented by the following general formula (1) and a solvent,

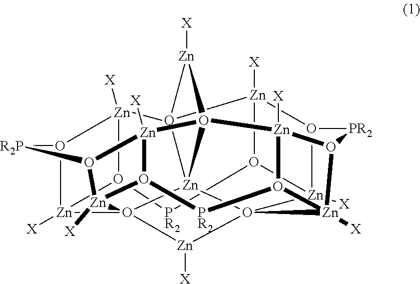

wherein R represents a hydrogen atom, a hydrocarbylcarbonyl group having 1 to 20 carbon atoms, or a hydrocarbyl group having 1 to 20 carbon atoms and optionally containing a heteroatom; and X represents a halogen atom or a hydrocarbyl group having 1 to 20 carbon atoms and optionally containing a heteroatom.

Hereinafter, the present invention will be described in detail, but the present invention is not limited thereto.

### [Resist Composition]

The inventive resist composition contains a metal complex having a particular structure and a solvent.

### [Metal Complex]

The metal complex contained in the inventive resist composition is represented by the following general formula (1). This metal complex has zinc atoms, which absorb EUV light with high efficiency, with high density, and therefore, is excellent in sensitivity and resolution. Furthermore, the complex has a hypophosphorous acid-type ligand, which has a high bond energy with metal atoms and can stabilize the complex, and a ligand (X), which has a low bond energy with metal atoms and has high photodecomposability, and therefore, not only does the inventive resist composition have even higher sensitivity, stability over time during storage of the resist composition and post PEB delay stability can be improved.

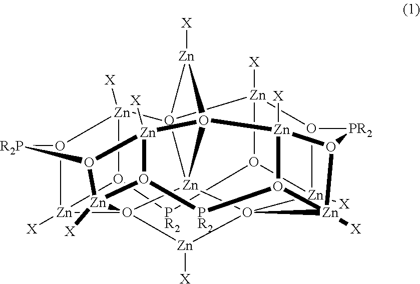

In the formula, R represents a hydrogen atom, a hydrocarbylcarbonyl group having 1 to 20 carbon atoms, or a hydrocarbyl group having 1 to 20 carbon atoms and optionally containing a heteroatom; and X represents a halogen atom or a hydrocarbyl group having 1 to 20 carbon atoms and optionally containing a heteroatom.

In the general formula (1), one of the two oxygen atoms (O) bonded to a single phosphorus atom (P) is bonded by a single bond, and the other is bonded by a double bond, but in the present description, depiction of double bonds has been simplified, and all double bonds are shown as single bonds for simplicity.

In the general formula (1), each R independently represents a hydrogen atom, a hydrocarbylcarbonyl group having 1 to 20 carbon atoms, or a hydrocarbyl group having 1 to 20 carbon atoms and optionally containing a heteroatom. The hydrocarbyl group and the hydrocarbyl moiety of the hydrocarbylcarbonyl group may be saturated or unsaturated, and may be linear, branched, or cyclic. Specific examples thereof include: alkyl groups having 1 to 20 carbon atoms, such as a methyl group, an ethyl group, an n-propyl group, an isopropyl group, an n-butyl group, an isobutyl group, a sec-butyl group, a tert-butyl group, a tert-pentyl group, an n-pentyl group, an n-hexyl group, an n-octyl group, a 2-ethylhexyl group, an n-nonyl group, and an n-decyl group; cyclic saturated hydrocarbyl groups having 3 to 20 carbon atoms, such as a cyclopentyl group, a cyclohexyl group, a cyclopentylmethyl group, a cyclopentylethyl group, a cyclopentylbutyl group, a cyclohexylmethyl group, a cyclohexylethyl group, a cyclohexylbutyl group, a norbornyl group, a tricyclo[5.2.1.0^{2,6}]decanyl group, an adamantyl group, and an adamantylmethyl group; alkenyl groups having 2 to 20 carbon atoms, such as a vinyl group and a 2-propenyl group; aryl groups having 6 to 20 carbon atoms, such as a phenyl group and a naphthyl group; and groups which are combinations of these groups. Furthermore, part or all of the hydrogen atoms of the hydrocarbyl group may be substituted with a group containing a heteroatom, such as an oxygen atom, a sulfur atom, a nitrogen atom, or a halogen atom, and part of the —CH₂— of the hydrocarbyl group may be substituted with a group containing a heteroatom such as an oxygen atom, a sulfur atom, or a nitrogen atom. The resulting hydrocarbyl group may contain a hydroxy group, a cyano group, a halogen atom, a carbonyl group, an ether bond, a thioether bond, an ester bond, a sulfonic acid ester bond, a carbonate bond, a carbamate bond, a lactone ring, a sultone ring, a carboxylic acid anhydride, etc. In the formula, the Rs may be identical to or different from each other.

In the general formula (1), each X independently represents a halogen atom or a hydrocarbyl group having 1 to 20 carbon atoms and optionally containing a heteroatom. Examples of the halogen atom include fluorine, chlorine, bromine, and iodine atoms. The hydrocarbyl group may be saturated or unsaturated, and may be linear, branched, or cyclic. Specific examples thereof include: alkyl groups having 1 to 20 carbon atoms, such as a methyl group, an ethyl group, an n-propyl group, an isopropyl group, an n-butyl group, an isobutyl group, a sec-butyl group, a tert-butyl group, a tert-pentyl group, an n-pentyl group, an n-hexyl group, an n-octyl group, a 2-ethylhexyl group, an n-nonyl group, and an n-decyl group; cyclic saturated hydrocarbyl groups having 3 to 20 carbon atoms, such as a cyclopentyl group, a cyclohexyl group, a cyclopentylmethyl group, a cyclopentylethyl group, a cyclopentylbutyl group, a cyclohexylmethyl group, a cyclohexylethyl group, a cyclohexylbutyl group, a norbornyl group, a tricyclo[5.2.1.0^{2,6}]decanyl group, an adamantyl group, and an adamantylmethyl group; alkenyl groups having 2 to 20 carbon atoms, such as a vinyl group and a 2-propenyl group; aryl groups having 6 to 20 carbon atoms, such as a phenyl group and a naphthyl group; and groups which are combinations of these groups. Furthermore, part or all of the hydrogen atoms of the hydrocarbyl group may be substituted with a group containing a heteroatom, such as an oxygen atom, a sulfur atom, a nitrogen atom, or a halogen atom, and part of the —CH₂— of the hydrocarbyl group may be substituted with a group containing a heteroatom such as an oxygen atom, a sulfur atom, or a nitrogen atom. The resulting hydrocarbyl group may contain a hydroxy group, a cyano group, a halogen atom, a carbonyl group, an ether bond, a thioether bond, an ester bond, a sulfonic acid ester bond, a carbonate bond, a carbamate bond, a lactone ring, a sultone ring, a carboxylic acid anhydride, etc. It is particularly preferable that the atom in the hydrocarbyl group that is bonded to the zinc atom is a carbon atom. In the formula, the Xs may be identical to or different from each other.

Specific examples of the metal complex represented by the general formula (1) include the following, but are not limited thereto. Note that, in the following formulae, Me represents a methyl group and Ph represents a phenyl group.

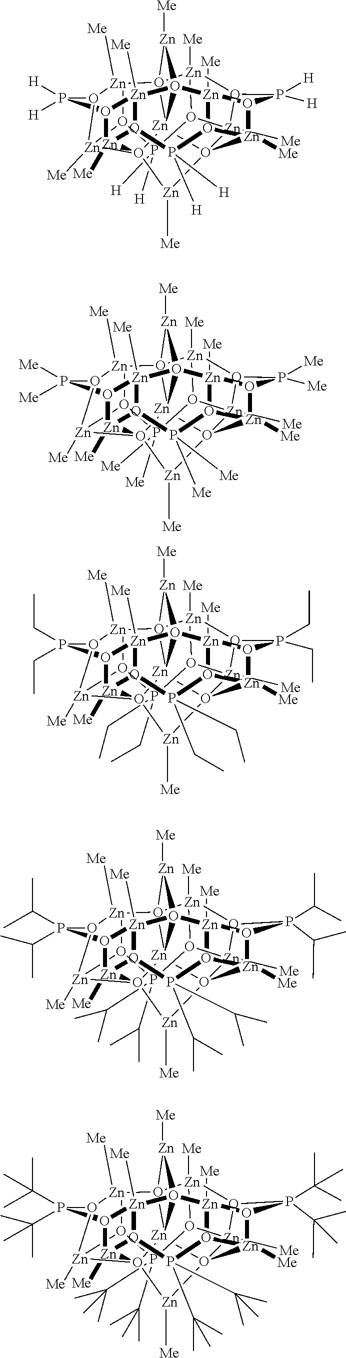

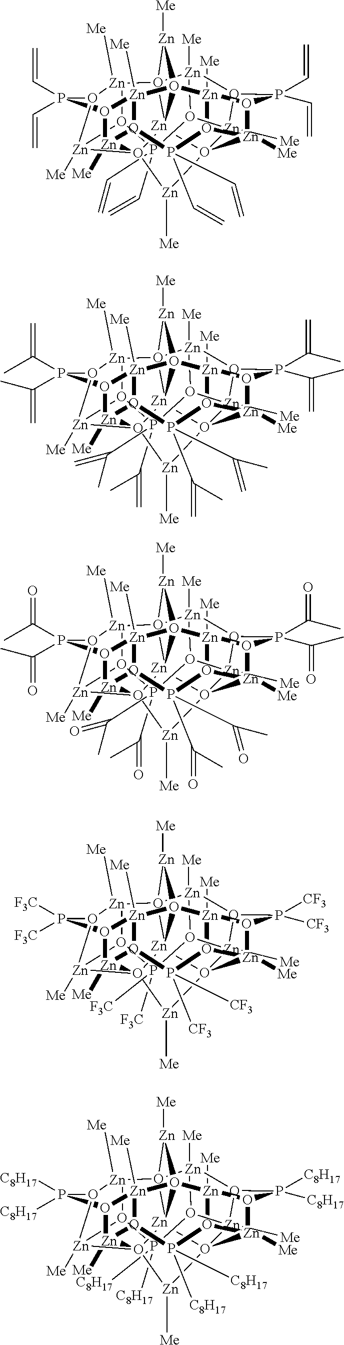

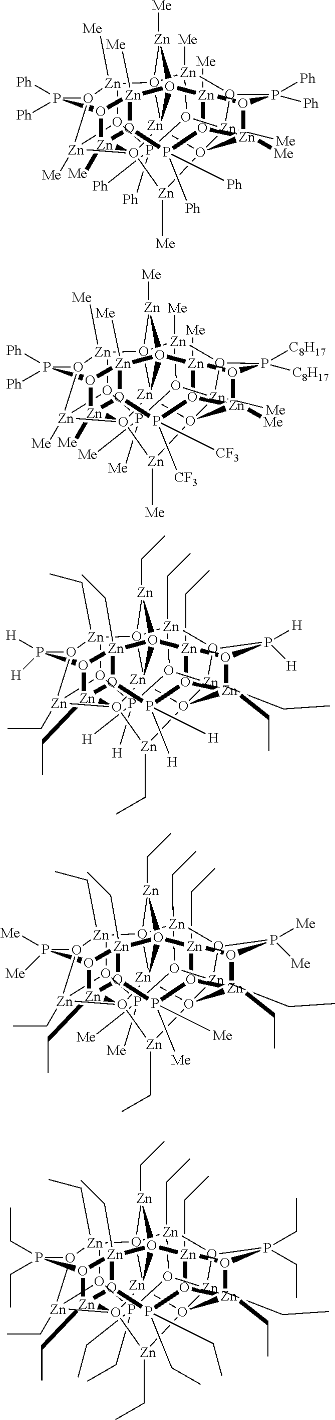

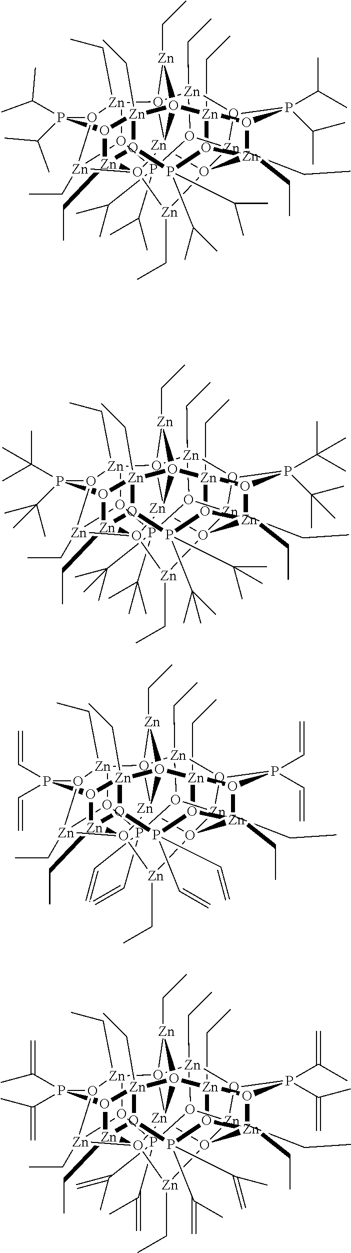

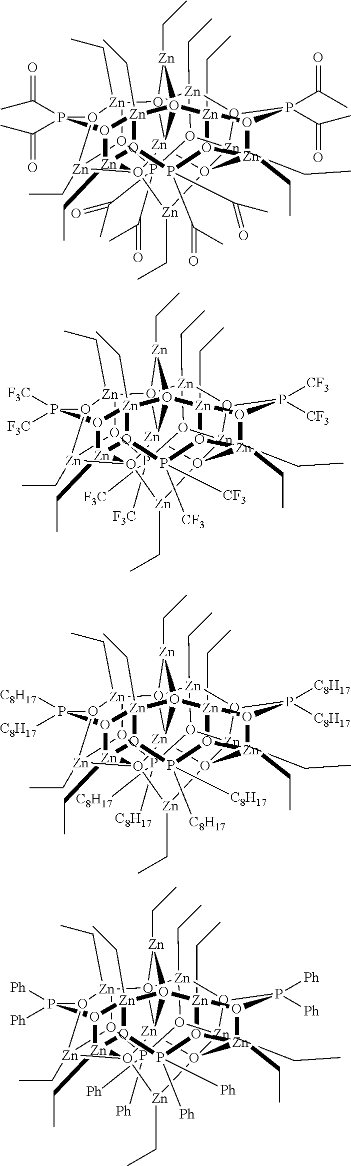

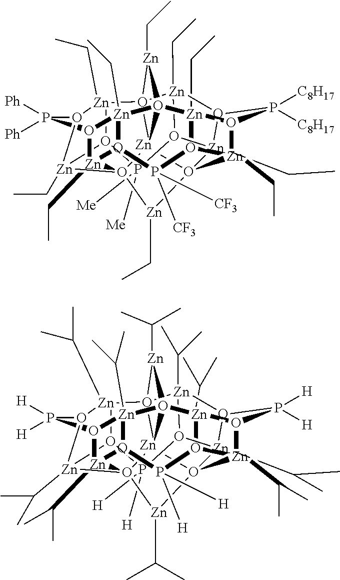

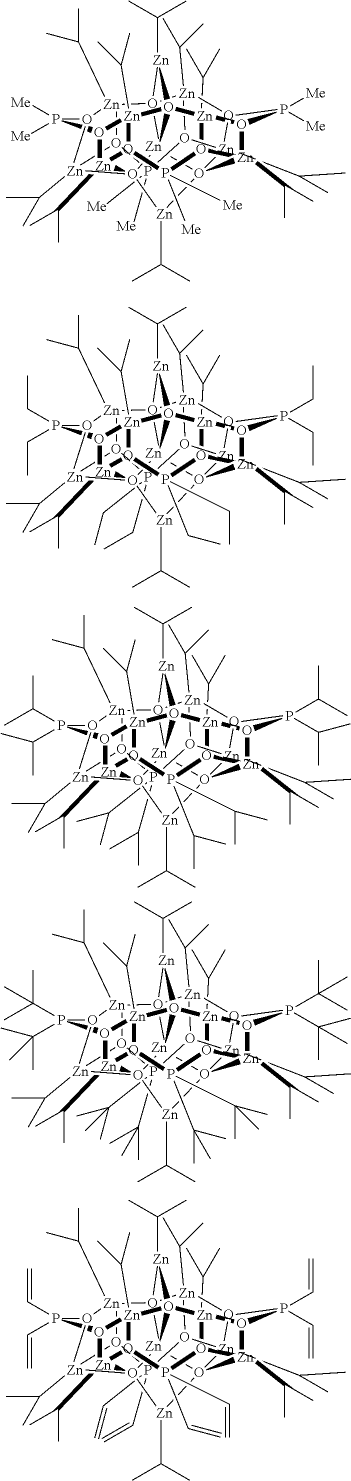

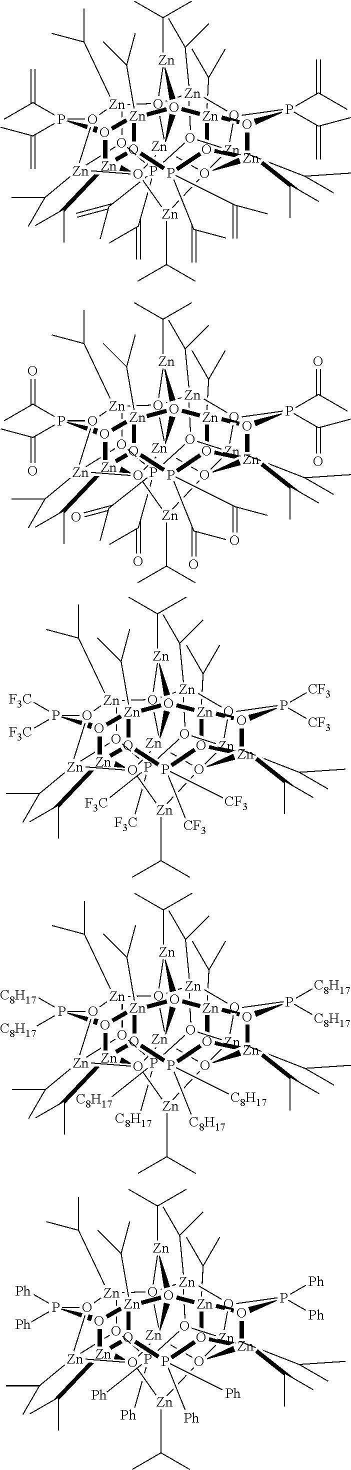

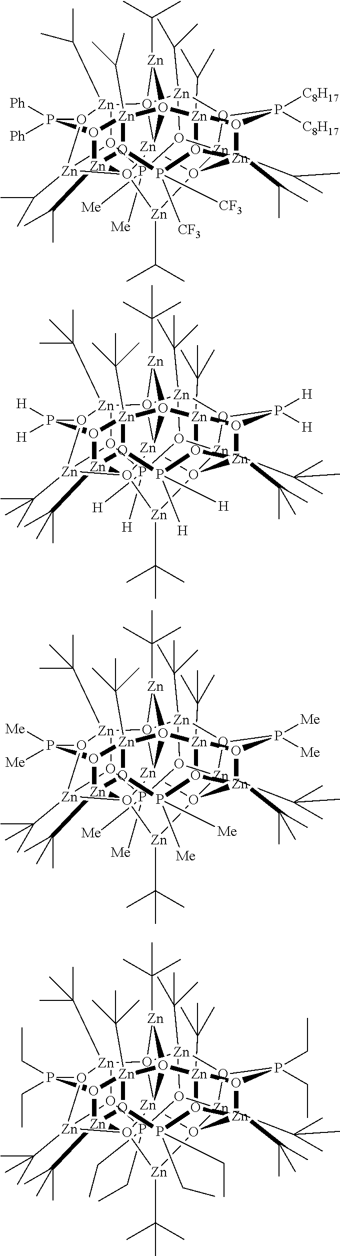

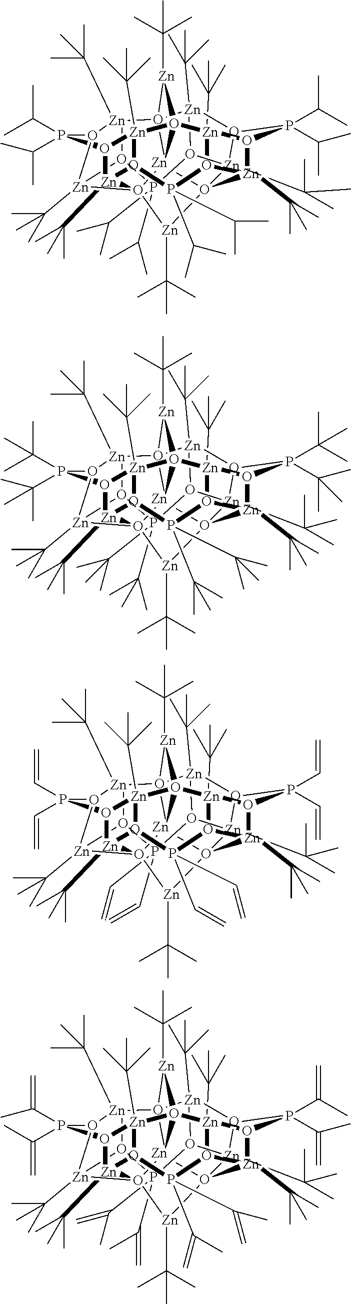

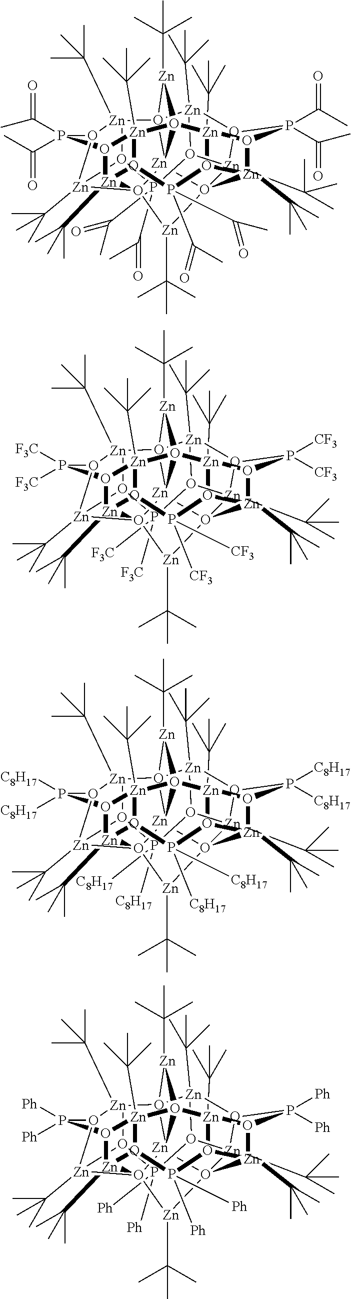

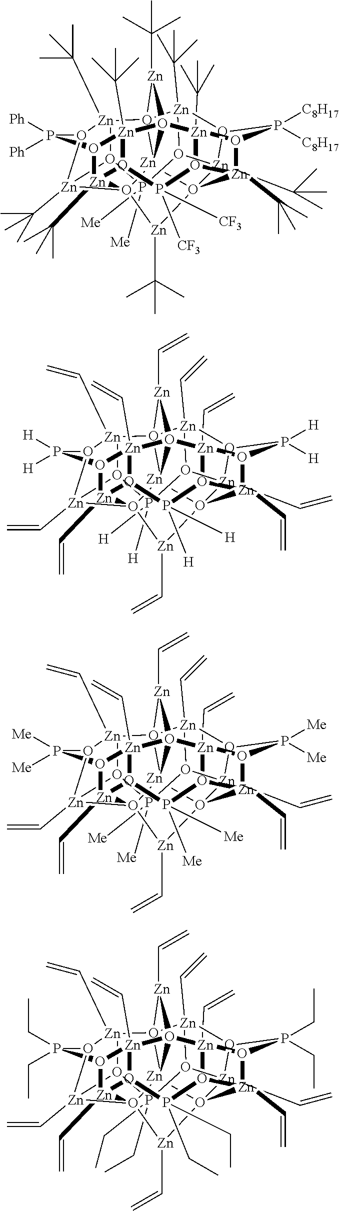

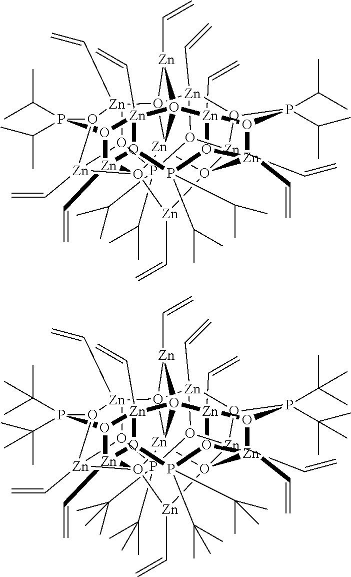

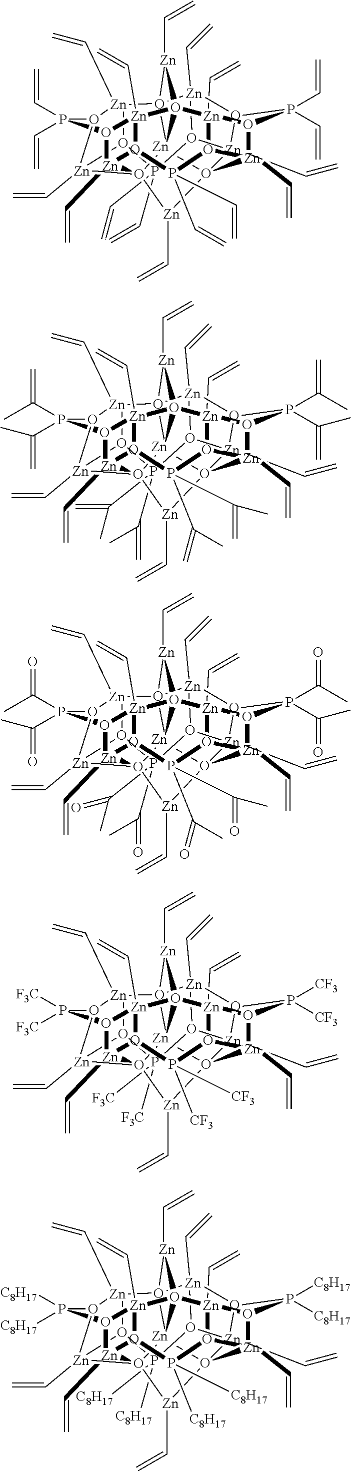

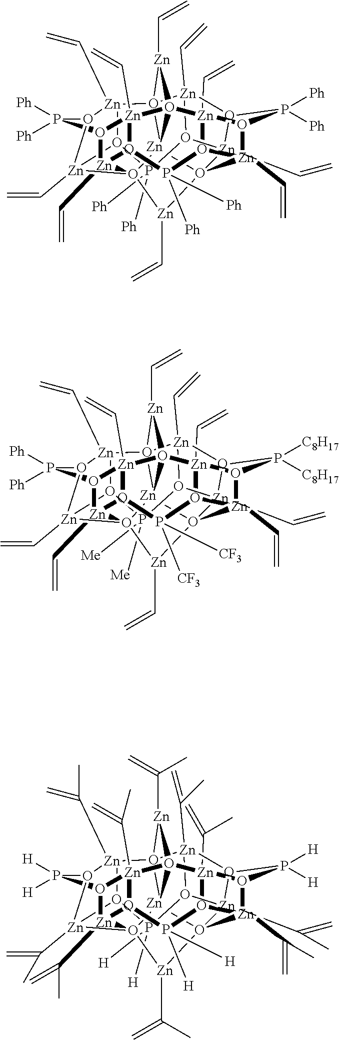

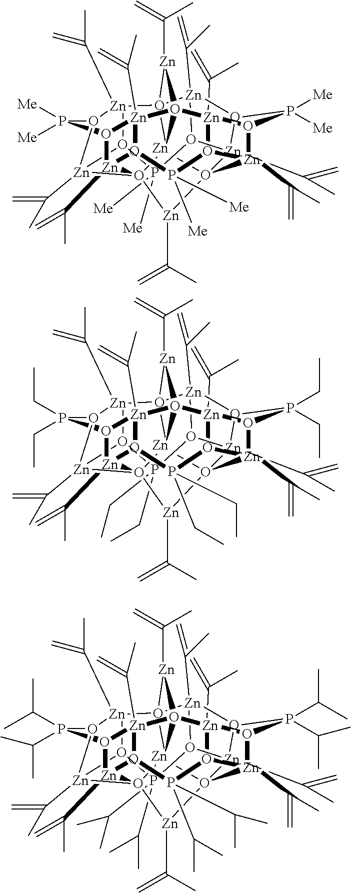

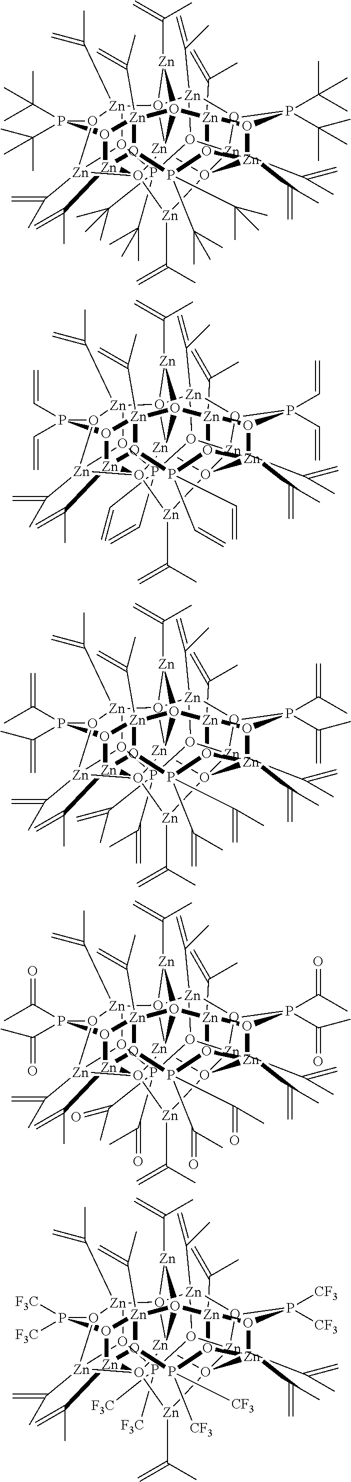

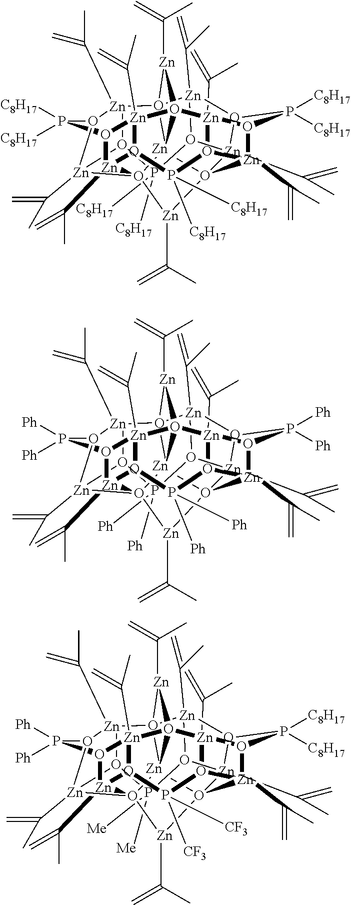

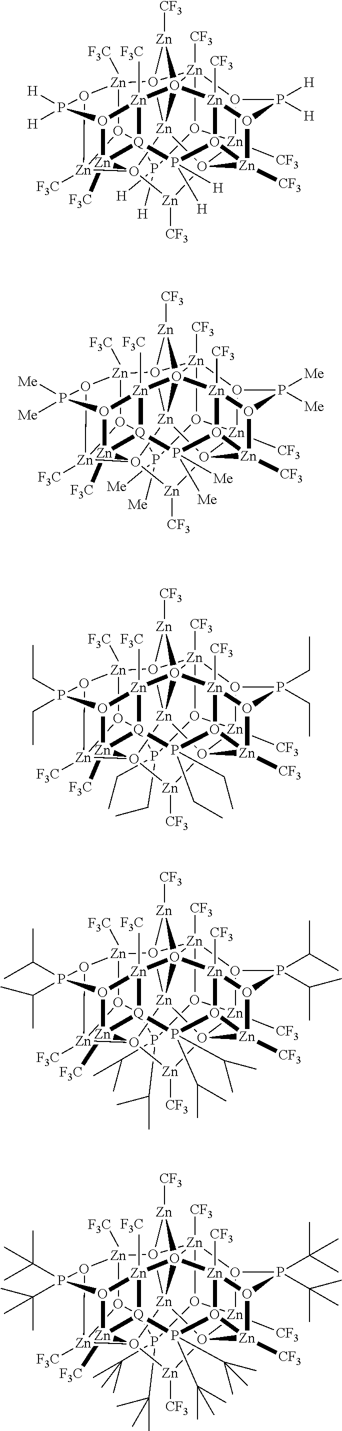

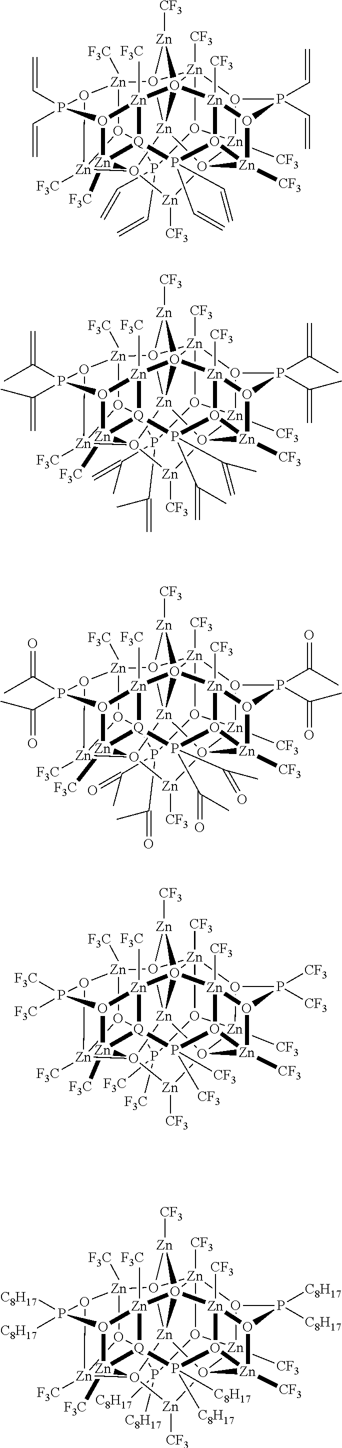

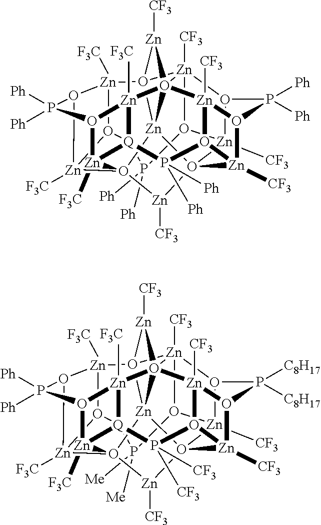

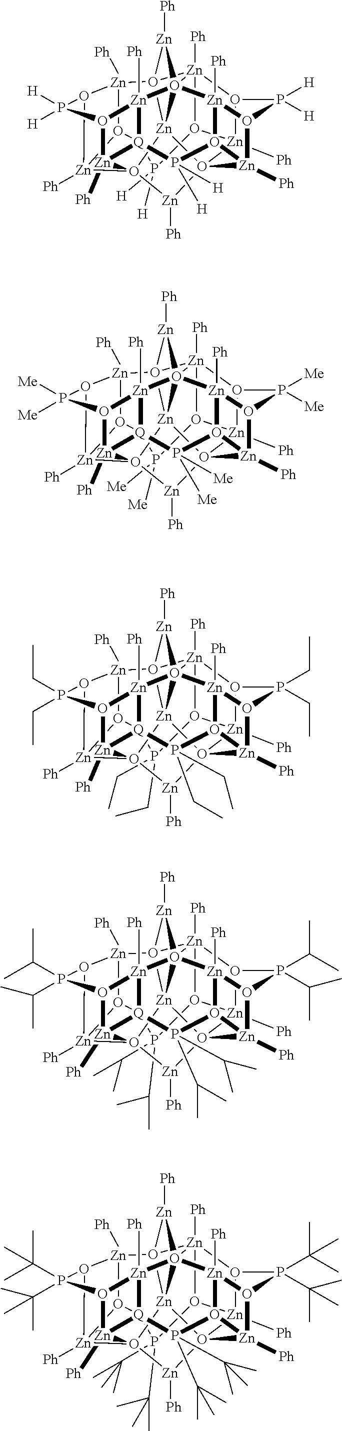

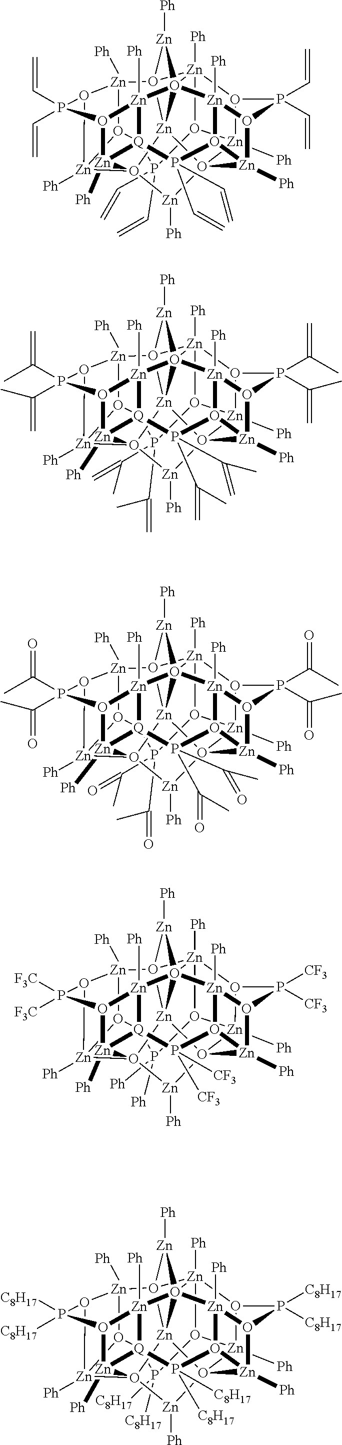

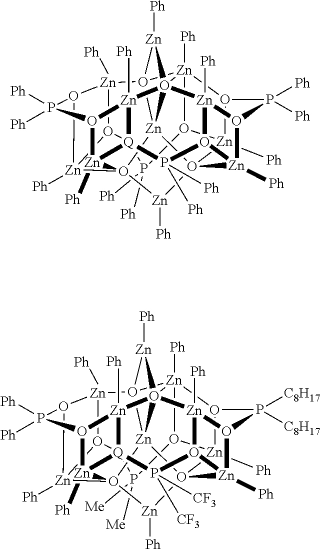

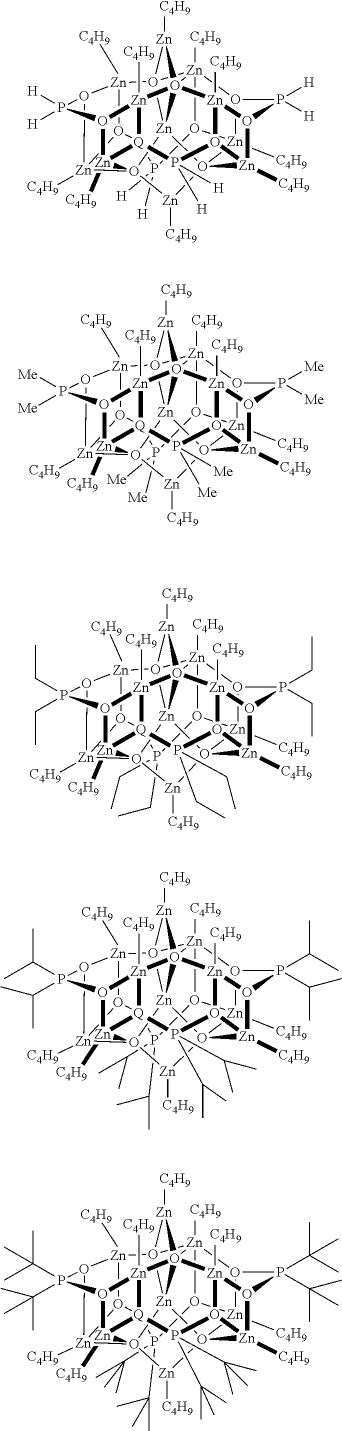

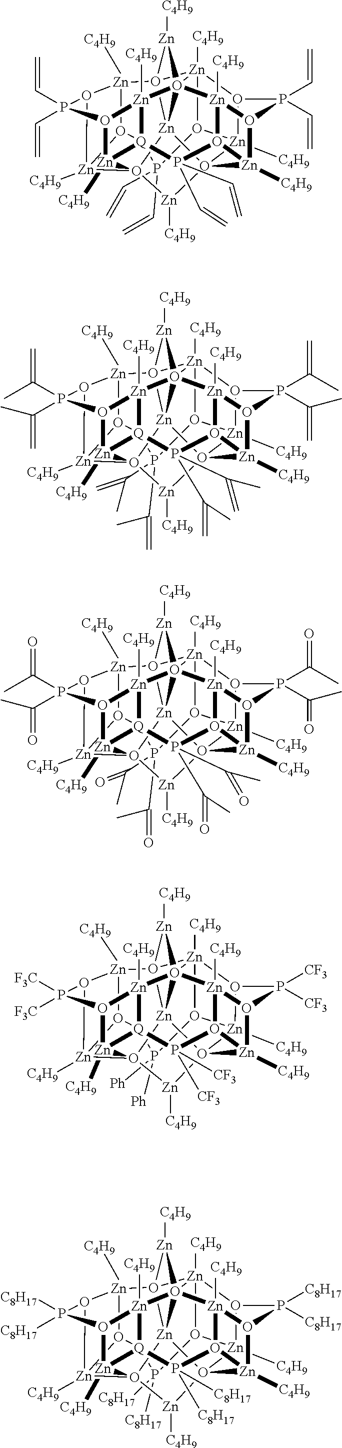

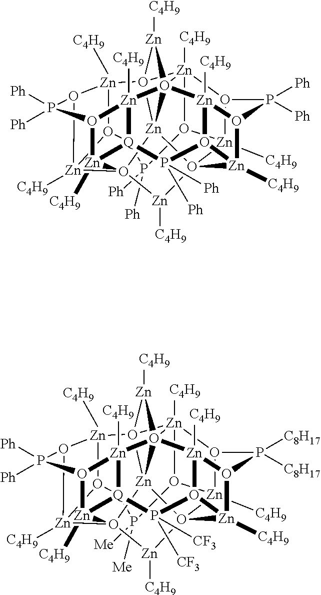

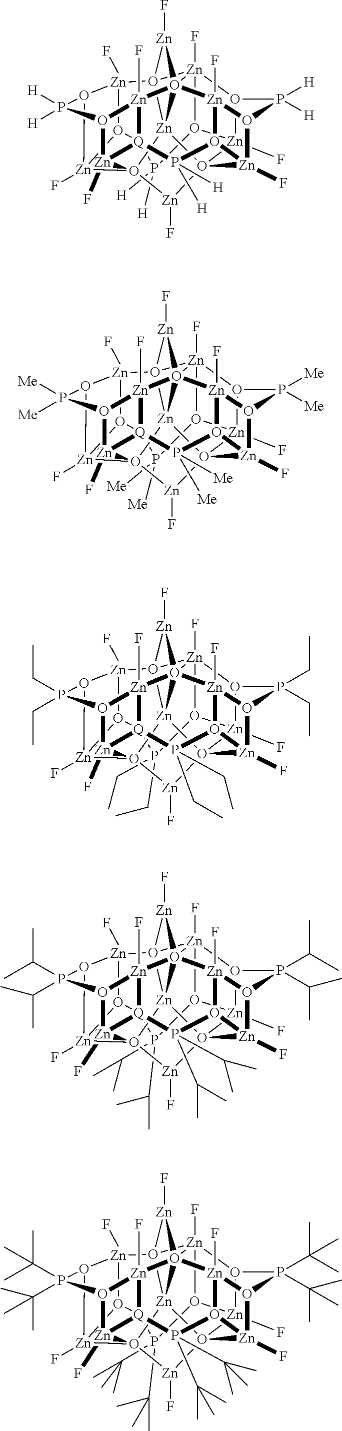

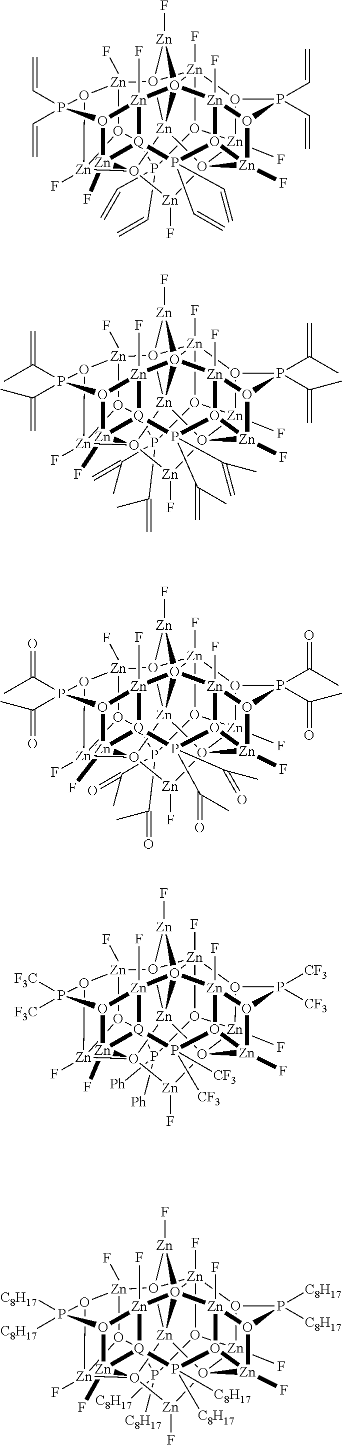

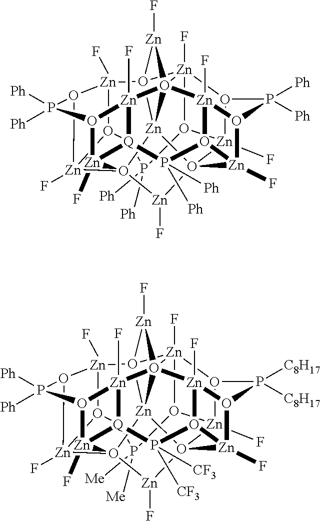

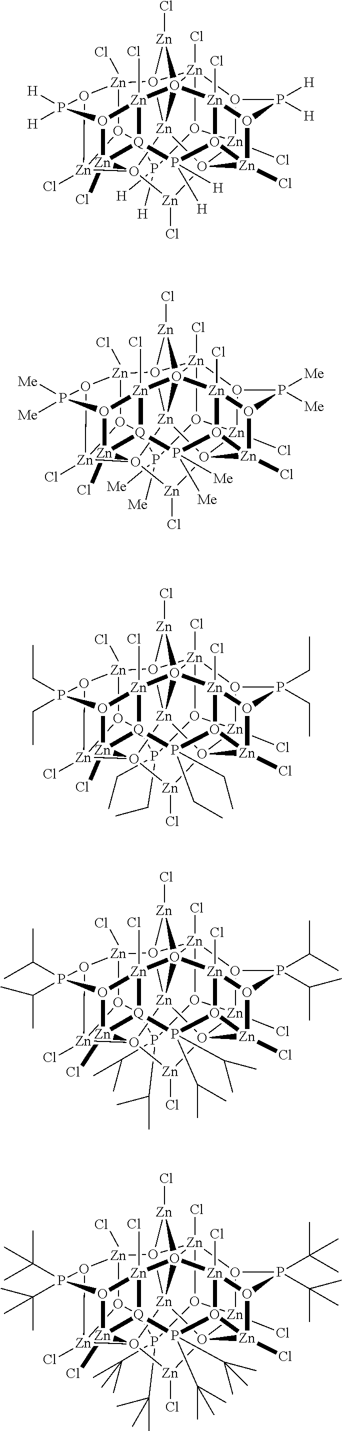

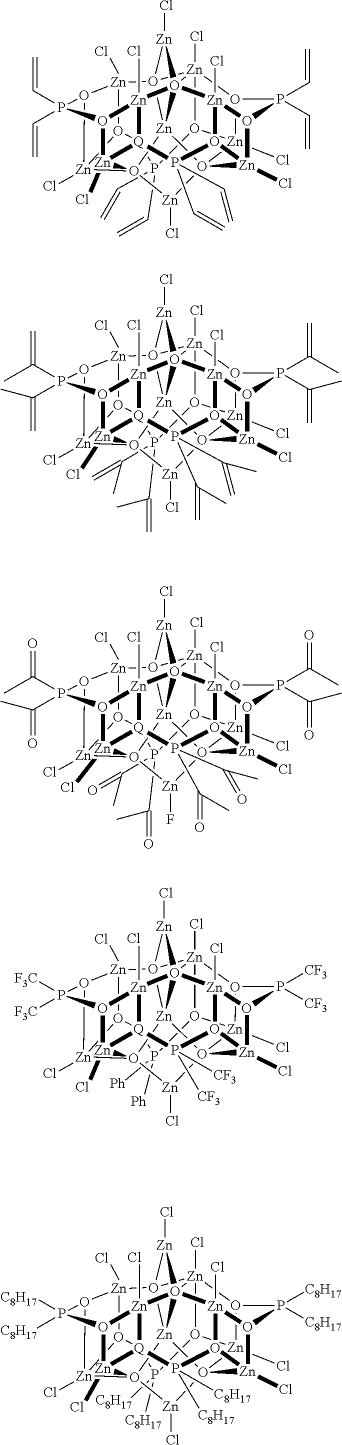

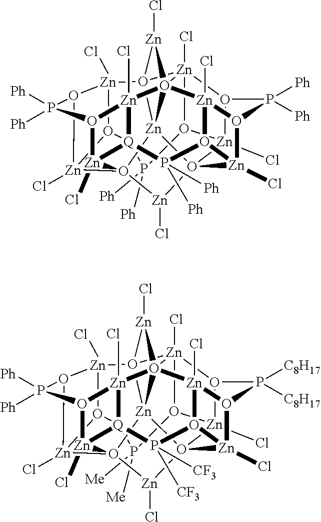

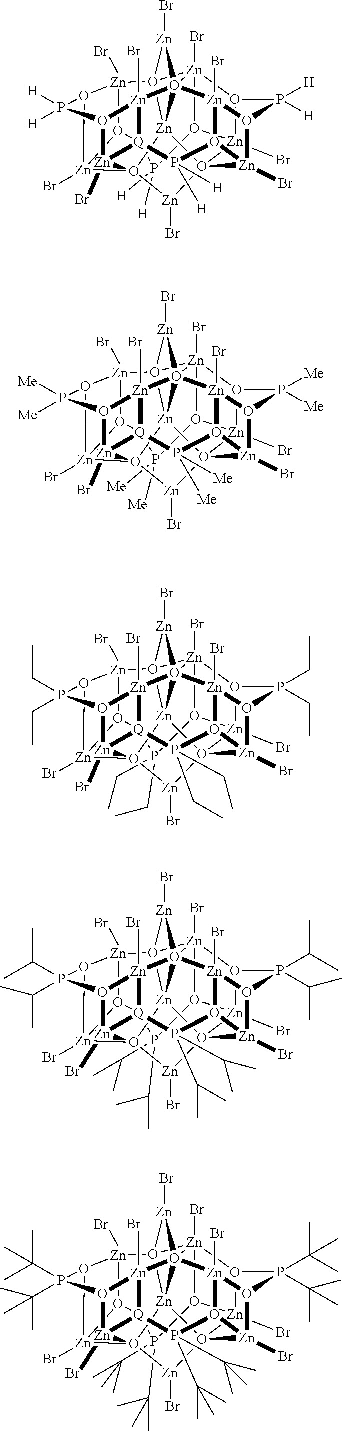

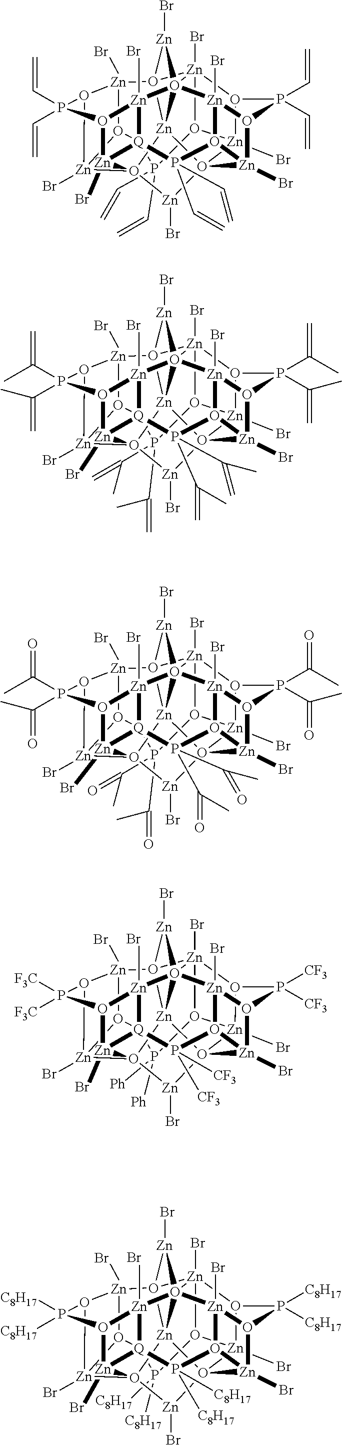

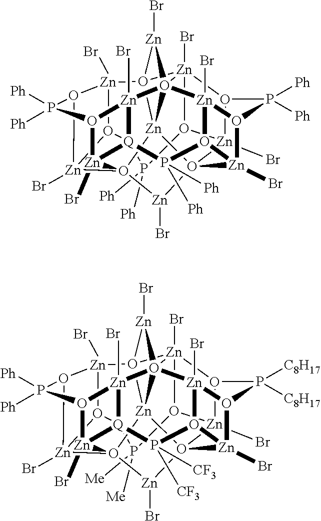

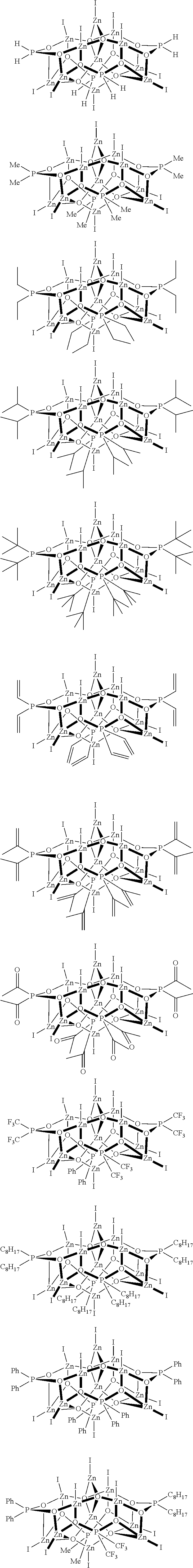

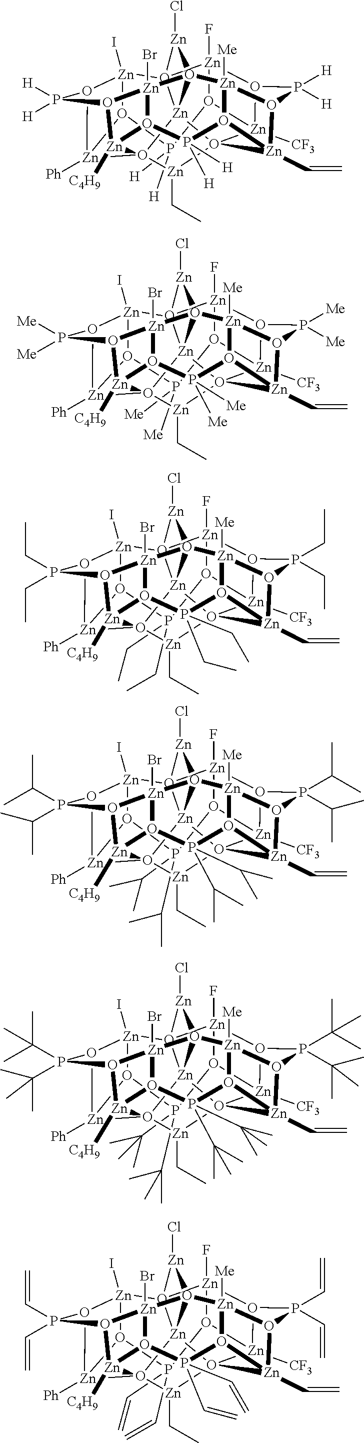

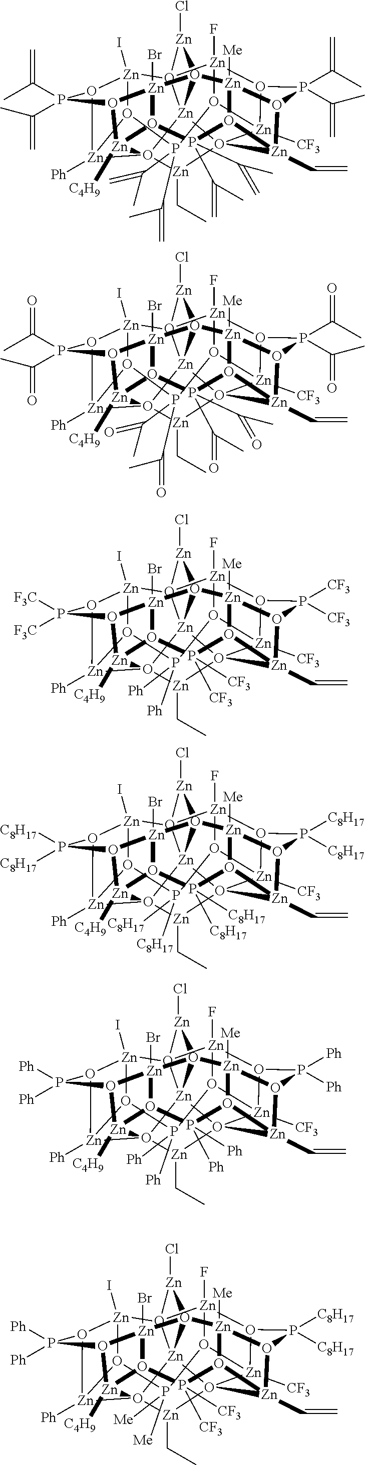

In a case where there are isomers of the metal complex depending on the arrangement of the ligands, a mixture of these isomers may be used, or only a single kind of isomer may be used. Furthermore, in a case where the metal complex is constituted by multiple kinds of ligands having different Rs or Xs, a single kind of metal complex in which the proportions of the ligands have been completely controlled may be used, or a mixture of metal complexes having different proportions of the ligands may be used.

One kind of the metal complex may be used, or two or more kinds thereof may be used in combination.

### [Solvent]

The inventive resist composition contains an organic solvent as a solvent. The organic solvent is not particularly limited as long as it dissolves the metal complex and allows film formation. Examples of such an organic solvent include: ketones, such as cyclohexanone and methyl-2-n-pentyl ketone; alcohols, such as 3-methoxybutanol, 3-methyl-3-methoxybutanol, 1-methoxy-2-propanol, 1-ethoxy-2-propanol, and diacetone alcohol; ethers, such as propylene glycol monomethyl ether, ethylene glycol monomethyl ether, propylene glycol monoethyl ether, ethylene glycol monoethyl ether, propylene glycol dimethyl ether, and diethylene glycol dimethyl ether; esters, such as propylene glycol monomethyl ether acetate (PGMEA), propylene glycol monoethyl ether acetate, ethyl lactate, ethyl pyruvate, butyl acetate, methyl 3-methoxypropionate, ethyl 3-ethoxypropionate, methyl 2-hydroxyisobutyrate, tert-butyl acetate, cyclohexyl acetate, tert-butyl propionate, and propylene glycol mono-tert-butyl ether acetate; lactones, such as γ-butyrolactone; carboxylic acids, such as acetic acid and propionic acid; aromatic materials, such as toluene, xylene, cresol, anisole, and benzotrifluoride; halogenated hydrocarbons, such as dichloromethane, chloroform, and carbon tetrachloride; and mixed solvents thereof.

The organic solvent is preferably contained in an amount of 200 to 20,000 parts by mass, more preferably 500 to 15,000 parts by mass, based on 100 parts by mass of the metal complex.

In the inventive resist composition, it is conjectured that development resistance in exposed portions and unexposed portions is altered by the photodecomposition of the metal complex, being the main component, and by the subsequent agglomeration or crosslinking reaction between partially decomposed metal complexes, and that contrast is thus exhibited. This reaction is not a catalytic reaction, and therefore, the inventive resist composition functions as a non-chemically amplified resist composition. Therefore, resolution is possible even in fine regions where it is difficult to form a pattern with a chemically amplified resist composition mainly containing a conventional multicomponent polymer. Particularly in EUV lithography, since the metal atom has a high ability to absorb EUV, stochastics is improved, and a resist composition also excellent in sensitivity and LWR can be achieved. Furthermore, since the metal complex converges to a thermally stable structure, the composition is also excellent in storage stability. In addition, there is no risk of performance being greatly altered over time after PEB.

### [Photo-Acid Generator]

The inventive resist composition may contain a photo-acid generator as a component other than the metal complex and the solvent. When a photo-acid generator is contained, an acid can be generated in exposed portions, and an effect of promoting the crosslinking reaction of the metal complex can be expected. Such a photo-acid generator is not particularly limited as long as it generates an acid upon irradiation with a high-energy beam, and one known as a photo-acid generator for conventional chemically amplified resist compositions can be used. Particularly preferably, the photo-acid generator generates a sulfonic acid, imide acid, or methide acid. Suitable photo-acid generators include sulfonium salt, iodonium salt, sulfonyldiazomethane, N-sulfonyloxyimide, oxime-O-sulfonate type acid generators, etc. Specific examples of the photo-acid generator include ones disclosed in paragraphs [0122] to [0142] of JP2008-111103A and ones disclosed in paragraphs [0127] to [0193] of JP2022-163697A.

When the inventive resist composition contains the photo-acid generator, the contained amount is preferably 0.01 to 20 mass % of all the solid contents. Note that, in the present invention, solid contents is a general term for the components other than the solvent out of all the components of the resist composition. One kind of the photo-acid generator may be used, or two or more kinds thereof may be used in combination.

### [Radical Scavenger]

The inventive resist composition may contain a radical scavenger as another component. When a radical scavenger is contained, the photoreaction during photolithography can be controlled, and sensitivity can be adjusted.

As the radical scavenger, it is possible to use hindered phenols, quinones, hindered amines, thiol compounds, etc. Specific examples of the hindered phenols include dibutylhydroxytoluene and 2,2′-methylenebis(4-methyl-6-tert-butylphenol). Specific examples of the quinones include 4-methoxyphenol (methoquinone) and hydroquinone. Specific examples of the hindered amines include 2,2,6,6-tetramethylpiperidine and 2,2,6,6-tetramethylpiperidine-N-oxy radical. Specific examples of the thiols include dodecanethiol and hexadecanethiol.

When the inventive resist composition contains the radical scavenger, the contained amount is preferably 0.01 to 10 mass % of all the solid contents. One kind of the radical scavenger may be used, or two or more kinds thereof may be used in combination.

### [Surfactant]

The inventive resist composition may contain a surfactant as another component. As the surfactant, those disclosed in JP2010-215608A and JP2011-016746A can be referred to. Among the surfactants disclosed in these publications, preferable are FC-4430 (manufactured by 3M Company), Surflon (registered trademark) S-381 (manufactured by AGC Seimi Chemical Co., Ltd.), OLFINE (registered trademark) E1004 (manufactured by Nissin Chemical Industry Co., Ltd.), KH-20 and KH-30 (manufactured by AGC Seimi Chemical Co., Ltd.), an oxetane ring-opened polymer represented by the following general formula (surf-1), etc.

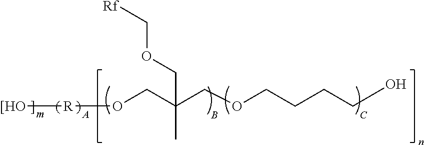

In the general formula (surf-1), R¹ represents an aliphatic group having a valency of 2 to 4 and having 2 to 5 carbon atoms. As the aliphatic group, examples of divalent groups include an ethylene group, a 1,4-butylene group, a 1,2-propylene group, a 2,2-dimethyl-1,3-propylene group, and a 1,5-pentylene group, and examples of trivalent or tetravalent groups include the following.

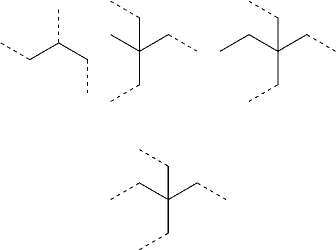

In the formulae, a broken line represents an attachment point, and each formula respectively represents a partial structure derived from glycerol, trimethylolethane, trimethylolpropane, and pentaerythritol.

Among these, a 1,4-butylene group, a 2,2-dimethyl-1,3-propylene group, etc. are preferable.

Rf represents a trifluoromethyl group or a pentafluoroethyl group, preferably a trifluoromethyl group. “m” represents an integer of 0 to 3, “n” represents an integer of 1 to 4, and the sum of “n” and “m” represents the valence of R¹ and is an integer of 2 to 4. A represents 1. B represents an integer of 2 to 25, preferably an integer of 4 to 20. C represents an integer of 0 to 10, preferably 0 or 1. Furthermore, each constitutional unit in the general formula (surf-1) does not define the arrangement, and the units may be bonded in blocks or at random. The production of the partially fluorinated oxetane ring-opened polymer-based surfactant is described in detail in U.S. Pat. No. 5,650,483A etc.

When the inventive resist composition contains the surfactant, the contained amount is preferably 0.001 to 20 parts by mass, more preferably 0.1 to 10 parts by mass, based on 100 parts by mass of the metal complex. One kind of the surfactant may be used, or two or more kinds thereof may be used in combination.

### [Laminate]

Furthermore, the present invention provides a laminate including:
a substrate; and
a resist film obtained from the above-described resist composition on the substrate.

In the inventive laminate, including a resist film obtained from the inventive resist composition, the resist film has high sensitivity, also exhibits excellent limiting resolution, is effective for precise fine processing, and in addition, is also excellent in post PEB delay stability. Therefore, the inventive laminate has a wide range of uses, and is highly useful in resist process technology.

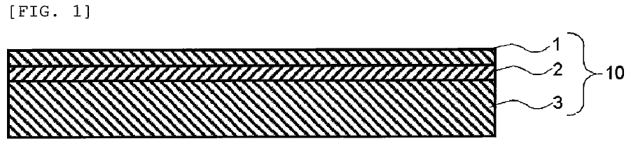

Furthermore, the inventive laminate may, like the laminate 10 shown in FIG. 1, further include a resist underlayer film 2 between the substrate 3 and the resist film 1, for example.

When a resist underlayer film is necessary for pattern formation, a resist underlayer film can also be disposed appropriately between the substrate and the resist film.

The resist film is not particularly limited as long as it is obtained from the inventive resist composition. For example, the resist film may be a film constituted by only the metal complex, or may be a film constituted by a product obtained by at least part of the metal complex undergoing a reaction caused by baking or a substance (e. g. water, oxygen, solvent, etc.) in the environment.

### [Patterning Process]

When the inventive resist composition is used for manufacturing various integrated circuits, a known lithography technique can be applied. Examples of patterning processes include a method including the steps of: forming a resist film by using the above-described resist composition on a substrate; exposing the resist film by using a high-energy beam; and developing the exposed resist film.

That is, the present invention provides a patterning process including the steps of:
forming a resist film by using the above-described resist composition on a substrate or on a resist underlayer film of a substrate on which the resist underlayer film has been laminated;
exposing the resist film by using a high-energy beam; and
developing the exposed resist film by using a developer.

Firstly, the inventive resist composition is applied onto a substrate for manufacturing an integrated circuit, on a resist underlayer film of a substrate (Si, SiO₂, SiN, SiON, TiN, WSi, BPSG, SOG, organic antireflective film, etc.) on which the resist underlayer film has been laminated, on a substrate for manufacturing a mask circuit, or on a resist underlayer film of a substrate (Cr, Cro, CrON, MoSi₂, SiO₂, etc.) on which the resist underlayer film has been laminated, by an appropriate coating process, for example, spin coating, roll coating, flow coating, dip coating, spray coating, doctor coating, etc., so that the thickness of the coating film is 0.01 to 2 μm, for example. The coating film thus obtained is prebaked on a hot plate preferably at 60 to 200° C. for 10 seconds to 30 minutes, more preferably 80 to 180° C. for 30 seconds to 20 minutes, for example. Thus, a resist film can be formed. Note that a resist underlayer film means a film formed between the substrate and the resist film in a multilayer resist process. The resist underlayer film is not particularly limited, and a conventionally known film can be used.

Subsequently, the resist film is exposed by using a high-energy beam. Specific examples of the high-energy beam include ultraviolet ray (g-line (436 nm), h-line (405 nm), i-line (365 nm), etc.), deep ultraviolet ray, electron beam (EB), extreme ultraviolet ray (EUV), X-ray, soft X-ray, excimer laser beam (KrF excimer laser beam, ArF excimer laser beam, etc.), Y-ray, and synchrotron radiation. As the high-energy beam, it is preferable to use an i-line, a KrF excimer laser beam, an ArF excimer laser beam, an electron beam, or an extreme ultraviolet ray. When ultraviolet ray, deep ultraviolet ray, EUV, X-ray, soft X-ray, excimer laser beam, γ-ray, synchrotron radiation, or the like is employed as the high-energy beam, the irradiation is performed directly or while using a mask for forming a target pattern at an exposure dose of preferably about 1 to 300 mJ/cm², more preferably about 10 to 200 mJ/cm². When an EB is employed as the high-energy beam, the writing is performed directly or while using a mask for forming a target pattern at an exposure dose of preferably about 0.1 to 2000 μC/cm², more preferably about 0.5 to 1500 μC/cm². Note that the inventive resist composition is particularly suitable for fine patterning with an EB or EUV, among the high-energy beams. That is, it is preferable to use an electron beam or an extreme ultraviolet ray as the high-energy beam.

To promote or terminate the reaction after exposure, PEB may be performed. When PEB is to be performed, PEB is preferably performed after the exposure on a hot plate or in an oven under the conditions of 30 to 200° C. for 10 seconds to 30 minutes, more preferably 60 to 180° C. for 30 seconds to 20 minutes.

The method for performing the development performed after exposure or after PEB can be a method using wet development or dry development. In the case of wet development, alkaline development and organic solvent development can be applied, and when a pattern is formed in the inventive resist composition, organic solvent development is preferable. Wet development is preferably performed on the exposed resist film preferably for 3 seconds to 3 minutes, more preferably 5 seconds to 2 minutes, by a conventional technique, such as a dip, puddle, or spray method, and thus, the target pattern is formed. The inventive resist composition is a negative type, and therefore, portions that have been irradiated with light become insoluble to the developer and portions that have not been irradiated dissolve.

Examples of organic solvents to be used as the developer include 2-octanone, 2-nonanone, 2-heptanone, 3-heptanone, 4-heptanone, 2-hexanone, 3-hexanone, diisobutyl ketone, methylcyclohexanone, acetophenone, methylacetophenone, propyl acetate, butyl acetate, isobutyl acetate, pentyl acetate, butenyl acetate, isopentyl acetate, propyl formate, cyclohexyl acetate, butyl formate, isobutyl formate, pentyl formate, isopentyl formate, methyl valerate, methyl pentenoate, methyl crotonate, ethyl crotonate, methyl propionate, ethyl propionate, ethyl 3-ethoxypropionate, methyl lactate, ethyl lactate, propyl lactate, butyl lactate, isobutyl lactate, pentyl lactate, isopentyl lactate, methyl 2-hydroxyisobutyrate, ethyl 2-hydroxyisobutyrate, methyl benzoate, ethyl benzoate, phenyl acetate, benzyl acetate, phenylmethyl acetate, phenylethyl acetate, benzyl formate, phenylethyl formate, methyl 3-phenylpropionate, benzyl propionate, 2-phenylethyl acetate, dichloromethane, chloroform, carbon tetrachloride, formic acid, acetic acid, and propionic acid. One kind of these organic solvents may be used, or two or more kinds thereof may be used in mixture.

After the development, rinsing is performed as necessary. The rinsing liquid is preferably a solvent that is miscible with the developer but does not dissolve the resist film. As such a solvent, it is preferable to use an alcohol having 3 to 10 carbon atoms, an ether compound having 8 to 12 carbon atoms, an alkane, alkene, alkyne, and aromatic solvent, each having 6 to 12 carbon atoms.

Specific examples of the alcohol having 3 to 10 carbon atoms include n-propyl alcohol, isopropyl alcohol, 1-butyl alcohol, 2-butyl alcohol, isobutyl alcohol, tert-butyl alcohol, 1-pentanol, 2-pentanol, 3-pentanol, tert-pentyl alcohol, neopentyl alcohol, 2-methyl-1-butanol, 3-methyl-1-butanol, 3-methyl-3-pentanol, cyclopentanol, 1-hexanol, 2-hexanol, 3-hexanol, 2,3-dimethyl-2-butanol, 3,3-dimethyl-1-butanol, 3,3-dimethyl-2-butanol, 2-ethyl-1-butanol, 2-methyl-1-pentanol, 2-methyl-2-pentanol, 2-methyl-3-pentanol, 3-methyl-1-pentanol, 3-methyl-2-pentanol, 3-methyl-3-pentanol, 4-methyl-1-pentanol, 4-methyl-2-pentanol, 4-methyl-3-pentanol, cyclohexanol, 1-octanol, etc.

Specific examples of the ether compound having 8 to 12 carbon atoms include di-n-butyl ether, diisobutyl ether, di-sec-butyl ether, di-n-pentyl ether, diisopentyl ether, di-sec-pentyl ether, di-tert-pentyl ether, di-n-hexyl ether, etc.

Specific examples of the alkane having 6 to 12 carbon atoms include hexane, heptane, octane, nonane, decane, undecane, dodecane, methylcyclopentane, dimethylcyclopentane, cyclohexane, methylcyclohexane, dimethylcyclohexane, cycloheptane, cyclooctane, cyclononane, etc. Specific examples of the alkene having 6 to 12 carbon atoms include hexene, heptene, octene, cyclohexene, methylcyclohexene, dimethylcyclohexene, cycloheptene, cyclooctene, etc. Specific examples of the alkyne having 6 to 12 carbon atoms include hexyne, heptyne, octyne, etc.

Specific examples of the aromatic solvent having 6 to 12 carbon atoms include toluene, xylene, ethylbenzene, isopropylbenzene, tert-butylbenzene, mesitylene, etc.

The rinsing can reduce resist pattern collapse and defect formation. Meanwhile, the rinsing is not necessarily essential, and the amount of the solvent used can be reduced by not performing the rinsing.

As a development method in the inventive patterning process, dry development is also applicable. Dry development is development where a developer is not used, and either exposed portions or unexposed portions are removed in an etching step using a gas. In the case of the present invention, the desired pattern can be formed by removing unexposed portions with an etching gas. For the dry etching, preferably used are gases containing oxygen, hydrogen, ammonia, halogen, etc. and containing nitrogen, helium, argon, carbon dioxide, or carbon monoxide for dilution.

### EXAMPLES

Hereinafter, the present invention will be specifically described with reference to Examples and Comparative Examples. However, the present invention is not limited to the Examples.

Metal complexes used in the Examples are ones represented by the following formulae (M-1) and (M-2).

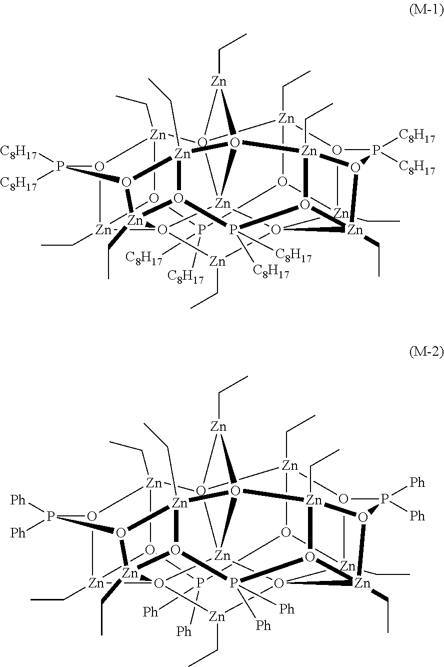

The metal complexes represented by the formulae (M-1) and (M-2) were synthesized with reference to Nature Communications, 2016, 7, 13008.

### [1] Preparation of Resist Compositions

### Examples 1-1 to 1-4 and Comparative Example 1-1

Each component was dissolved in a solvent in the constitution shown in Table 1, and the obtained solution was filtered with a 0.2-μm Teflon (registered trademark) filter to prepare inventive resist compositions R-1 to R-4 and a comparative resist composition CR-1.

TABLE 1

| | | Compo- | Compo- | Compo- | |
|---|---|---|---|---|---|
| | Resist | nent A | nent B | nent C | Solvent |
| | compo- | (parts by | (parts by | (parts by | (parts by |
| | sition | mass) | mass) | mass) | mass) |
| Example 1-1 | R-1 | M-1 | — | — | PGMEA |
| | | (20.0) | | | (1000) |
| Example 1-2 | R-2 | M-2 | — | — | Chloroform |
| | | (20.0) | | | (1000) |
| Example 1-3 | R-3 | M-2 | P-1 | — | Chloroform |
| | | (20.0) | (19) | | (1000) |
| Example 1-4 | R-4 | M-2 | — | Sc-1 | Chloroform |
| | | (20.0) | | (0.01) | (1000) |
| Comparative | CR-1 | CM-1 | — | — | Chloroform |
| Example 1-1 | | (20.0) | | | (1000) |

In Table 1, the component A is a metal complex, the component B is a photo-acid generator, and the component C is a radical scavenger. The structures of the metal complexes (M-1) and (M-2) to be used as the component A are as described above. Details of the components B and C are as follows.
P-1: triphenylsulfonium tosylate
Sc-1: dibutylhydroxytoluene

In Table 1, PGMEA represents propylene glycol monomethyl ether acetate.

In Table 1, CM-1 (tin compound), used in Comparative Example 1-1, was synthesized according to Angewandte Chemie, International Edition (2017), 56 (34), 10140-10144. The structure of CM-1 is as follows.

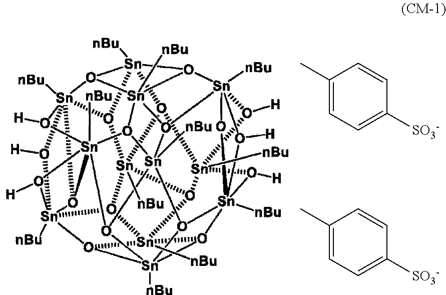

### [2] EB Lithography Evaluation

### Examples 2-1 to 2-4 and Comparative Example 2-1

Each of the resist compositions (R-1 to R-4 and CR-1) was applied by spin-coating onto a Si substrate on which an antireflective film DUV-42, manufactured by Nissan Chemical Corporation, was formed with 60 nm in film thickness, and prebaked by using a hot plate at 100° C. for 60 seconds to form a resist film having a film thickness of 40 nm. The resist film was exposed using an EB writing apparatus (ELS-F125, acceleration voltage 125 kV) manufactured by Elionix Inc., PEB was performed on a hot plate at the temperature shown in Table 2 for 60 seconds, and development was performed using 2-heptanone as a developer for 30 seconds to form a pattern. As a result, a negative line-and-space (LS) pattern having a space width of 20 nm and a pitch of 40 nm was obtained. Regarding the obtained LS pattern, sensitivity, LWR, and limiting resolution were evaluated according to the following methods. The results are shown in Table 2.

### [Sensitivity Evaluation]

The LS pattern was observed with an electron microscope, and an optimum exposure dose Eop (μC/cm²) to yield the LS pattern with 20 nm in space width and 40 nm in pitch was determined to specify this value as sensitivity.

### [LWR Evaluation]

In the LS pattern obtained by irradiation at the optimum exposure dose, sizes in ten positions in the longitudinal direction of the space width were measured with a CD-SEM (CG-5000), manufactured by Hitachi High-Technologies Corporation. From the results, a tripled value (3σ) of a standard variation (σ) was determined as LWR. A smaller LWR value can yield a pattern with smaller roughness and a more uniform space width.

### [Limiting Resolution Evaluation]

A pattern was formed while gradually increasing the exposure dose from the optimum exposure dose, and in this event, the limit of the line width (nm) at which resolution is possible was determined using a length-measurement SEM (CG-6300), manufactured by Hitachi High-Technologies Corporation, to specify this value as limiting resolution (nm). A smaller value indicates that it is possible to form a finer pattern with better limiting resolution.

### [Post PEB Delay Stability Evaluation]

After exposure at the optimum exposure dose, PEB and development were performed under the above-described conditions. In this event, a wafer (PPD 0 h) patterned by development without post PEB delay and a wafer (PPD 6 h) patterned by development after 6 hours of post PEB delay were prepared. The line widths of these wafers were determined using a length-measurement SEM (CG-6300), manufactured by Hitachi High-Technologies Corporation, and the change (APPD) in line width (CD) due to post PEB delay was determined. The results are shown in Table 2.

TABLE 2

| | | | | | Limiting | | | |
|---|---|---|---|---|---|---|---|---|
| | Resist | PEB | Eop | LWR | resolution | PPD 0 h | PPD 6 h | ΔPPD |
| | composition | (° C.) | (μC/cm²) | (nm) | (nm) | CD (nm) | CD (nm) | CD (nm) |
| Example 2-1 | R-1 | 150 | 1350 | 3.3 | 12.6 | 19.9 | 20.2 | 0.3 |
| Example 2-2 | R-2 | 150 | 1250 | 3.3 | 12.2 | 20.1 | 20.2 | 0.1 |
| Example 2-3 | R-3 | 150 | 1100 | 3.5 | 12.6 | 20.3 | 20.5 | 0.2 |
| Example 2-4 | R-4 | 150 | 1450 | 3.4 | 12.9 | 20.1 | 20.3 | 0.2 |
| Comparative | CR-1 | 170 | 3200 | 4.7 | 18.6 | 20.1 | 25.2 | 5.1 |
| Example 2-1 | | | | | | | | |

From the results shown in Table 2, it was found that the inventive resist compositions R-1 to R-4 were excellent in LWR and limiting resolution in negative patterning by organic solvent development using EB lithography. Furthermore, it was observed that there was little change in CD even with a post PEB delay, and that the compositions were also stable after patterning. Furthermore, the inventive resist compositions have zinc atoms, having a high ability to absorb EUV light, with high density, and therefore, are expected to have considerably high sensitivity in EUV lithography.

On the other hand, it was found that the comparative resist composition CR-1 had poor LWR and limiting resolution in negative patterning by organic solvent development using EB lithography. Furthermore, it was observed that there was a great change in CD after post PEB delay, and that the composition was also unstable after patterning.

### [3] Storage Stability Evaluation

### Examples 3-1 to 3-4 and Comparative Example 3-1

It was visually observed whether or not precipitation had occurred after leaving each of the resist compositions (R-1 to R-4 and CR-1) for a particular period under conditions of normal temperature (20±5° C.). In this event, a composition which was possible to store for 6 or more months without precipitation occurring was evaluated as “Good”, and a composition in which precipitation occurred in less than 6 months was evaluated as “Poor”. The results are shown in Table 3.

TABLE 3

| | Resist composition | Storage stability |
|---|---|---|
| Example 3-1 | R-1 | Good |
| Example 3-2 | R-2 | Good |
| Example 3-3 | R-3 | Good |
| Example 3-4 | R-4 | Good |
| Comparative | CR-1 | Poor |
| Example 3-1 | | |

From the results shown in Table 3, it was shown that the inventive resist compositions R-1 to R-4 were excellent in storage stability and had good handleability.

On the other hand, it was shown that the comparative resist composition CR-1 had poor storage stability, and therefore had poor handleability.

It should be noted that the present invention is not limited to the above-described embodiments. The embodiments are just examples, and any examples that have substantially the same feature and demonstrate the same functions and effects as those in the technical concept disclosed in claims of the present invention are included in the technical scope of the present invention.

1. A resist composition comprising a metal complex represented by the following general formula (1) and a solvent, 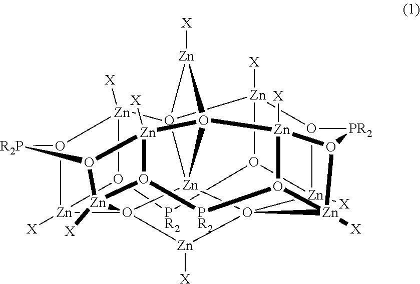
wherein R represents a hydrogen atom, a hydrocarbylcarbonyl group having 1 to 20 carbon atoms, or a hydrocarbyl group having 1 to 20 carbon atoms and optionally containing a heteroatom; and X represents a halogen atom or a hydrocarbyl group having 1 to 20 carbon atoms and optionally containing a heteroatom.

2. A laminate comprising:
a substrate; and
a resist film obtained from the resist composition according to claim 1 on the substrate.

3. The laminate according to claim 2, further comprising a resist underlayer film between the substrate and the resist film.

4. A patterning process comprising the steps of:
forming a resist film by using the resist composition according to claim 1 on a substrate or on a resist underlayer film of a substrate on which the resist underlayer film has been laminated;
exposing the resist film by using a high-energy beam; and
developing the exposed resist film by using a developer.

5. The patterning process according to claim 4, wherein the high-energy beam used is an electron beam or an extreme ultraviolet ray.
